(19) United States
(12) Patent Application Publication
(10) Pub. No.: US 2026/0106631 A1
(43) Pub. Date: Apr. 16, 2026

(54) Fast BF Decoder with Column Zone Convergence Detection

(71) Applicant: SK hynix Inc., Gyeonggi-do (KR)

(72) Inventors: Fan ZHANG, San Jose, CA (US); Meysam ASADI, San Jose, CA (US); Qiuju DIAO, San Jose, CA (US)

(21) Appl. No.: 18/912,466

(22) Filed: Oct. 10, 2024

(51) Int. Cl. H03M 13/11

(52) U.S. Cl. CPC H03M 13/1108; H03M 13/1148

(57) ABSTRACT

A method for operating a BF decoder and an associated memory system utilizing the BF decoder. The method includes a) providing a parity check matrix having column zones with different column weights, b) bit-flip BF decoding read codewords from a memory, the read codewords having errors, and the BF decoding producing decoded codewords with a measured error rate determined with the parity check matrix, and c) upon BF iteration to reduce the measured error rate, skipping column zones of the parity check matrix variables which have shown zone convergence to correct bit values in the decoded codewords.

### BACKGROUND

### 1. Field

Embodiments of the present disclosure relate to a memory system with decoders, and method of operating such system and decoders.

### 2. Description of the Related Art

The computer environment paradigm has shifted to ubiquitous computing systems that can be used anytime and anywhere. As a result, the use of portable electronic devices such as mobile phones, digital cameras, and notebook computers has rapidly increased. These portable electronic devices generally use a memory system having memory device(s), that is, data storage device(s). The data storage device is used as a main memory device or an auxiliary memory device of the portable electronic devices.

Data storage devices using memory devices provide excellent stability, durability, high information access speed, and low power consumption, since they have no moving parts. Examples of data storage devices having such advantages include universal serial bus (USB) memory devices, memory cards having various interfaces, and solid state drives (SSD).

The SSD may include flash memory components and a controller, which includes the electronics that bridge the flash memory components to the SSD input/output (I/O) interfaces. The SSD controller can include an embedded processor that can execute functional components such as firmware. The SSD functional components are device specific, and in most cases, can be updated.

The two main types of flash memory components are named after the NAND and NOR logic gates. The individual flash memory cells exhibit internal characteristics similar to those of their corresponding gates. The NAND-type flash memory may be written and read in blocks (or pages) which are generally much smaller than the entire memory space. The NOR-type flash allows a single machine word (byte) to be written to an erased location or read independently. The NAND-type operates primarily in memory cards, USB flash drives, solid-state drives, and similar products, for general storage and transfer of data.

NAND flash-based storage devices have been widely adopted because of their faster read/write performance, lower power consumption, and shock proof features. In general, however, they are more expensive compared to hard disk drives (HDD). To bring costs down, NAND flash manufacturers have been pushing the limits of their fabrication processes towards 20 nm and lower, which often leads to a shorter usable lifespan and a decrease in data reliability. As such, a much more powerful error correction code (ECC) is required over traditional Bose-Chaudhuri-Hocquenghem (BCH) codes to overcome the associated noises and interferences, and thus improve the data integrity. One such code for the ECC is low-density parity-check (LDPC) code. Various algorithms can be utilized for decoding LDPC codes.

There are different iterative decoding algorithms for LDPC codes and associated decoders, such as bit-flipping (BF) decoding algorithms, belief-propagation (BP) decoding algorithms, sum-product (SP) decoding algorithms, min-sum (MS) decoding algorithms, Min-Max decoding algorithms, etc. Some offer speed, while others are more capable at higher noise levels. Multiple decoding algorithms may be used in a particular system to enable different codewords to be decoded using different decoders depending on conditions such as noise level and interference.

In this context, embodiments of the present invention arise.

### SUMMARY

Aspects of the present invention include a method for operating an BF decoder. The method includes a) providing a parity check matrix having column zones with different column weights, b) bit-flip BF decoding read codewords from a memory, the read codewords having errors, and the BF decoding producing decoded codewords with a measured error rate determined with the parity check matrix, and c) upon BF iteration to reduce the measured error rate, skipping column zones of the parity check matrix variables which have shown zone convergence where the decoded codewords contain correct bit values.

Further aspects of the present invention include a memory system comprising a memory device, and a bit-flip (BF) decoder in communication with a storage of the memory device, wherein the BF decoder is configured to: provide a parity check matrix having column zones with different column weights; bit-flip BF decode read codewords from a memory, the read codewords having errors, and the BF decoding producing decoded codewords with a measured error rate determined with the parity check matrix; and upon BF iteration to reduce the measured error rate, skip column zones of the parity check matrix variables which have shown zone convergence where the decoded codewords contain correct bit values.

Other features, aspects and advantages of the present invention will become clear in view of the following description and accompanying the drawings.

### BRIEF DESCRIPTION OF THE DRAWINGS

FIG. 1 is a block diagram schematically illustrating a memory system in accordance with an embodiment of the present invention.

FIG. 2 is a block diagram illustrating a memory system in accordance with an embodiment of the present invention.

FIG. 3 is a circuit diagram illustrating a memory block of a memory device of a memory system in accordance with an embodiment of the present invention.

FIG. 4 is a diagram of an exemplary memory system in accordance with an embodiment of the present invention.

FIG. 5 is a diagram of an exemplary memory system including different decoders in accordance with an embodiment of the present invention.

FIG. 6 is a depiction of a matrix of a LDPC code.

FIGS. 7A and 7B illustrate a Tanner graph representation of the LDPC code and user bits, check nodes and parity bits.

FIG. 8 is a depiction of a parity check matrix in accordance with one embodiment of the present invention.

FIG. 9 is a depiction of another parity check matrix in accordance with one embodiment of the present invention.

FIG. 10 is a flowchart depicting a method for operating an BF decoder in accordance with one embodiment of the present invention.

### DETAILED DESCRIPTION

Various embodiments are described below in more detail with reference to the accompanying drawings. The present invention may, however, be embodied in different forms and should not be construed as limited to the embodiments set forth herein. Rather, these embodiments are provided so that this disclosure is thorough and complete and fully conveys the scope of the present invention to those skilled in the art. Moreover, reference herein to “an embodiment,” “another embodiment,” or the like is not necessarily to only one embodiment, and different references to any such phrases is not necessarily to the same embodiment(s). Throughout the disclosure, like reference numerals refer to like parts in the figures and embodiments of the present invention.

The invention can be implemented in numerous ways, including as a process; an apparatus; a system; a composition of matter; a computer program product embodied on a computer readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily configured to perform the task at a given time or a specific component that is manufactured to perform the task. As used herein, the term ‘processor’ refers to one or more devices, circuits, and/or processing cores suitable for processing data, such as computer program instructions.

A detailed description of embodiments of the invention is provided below along with accompanying figures that illustrate aspects of the invention. The invention is described in connection with such embodiments, but the invention is not limited to any embodiment. The scope of the invention is limited only by the claims, and the invention encompasses numerous alternatives, modifications and equivalents. Numerous specific details are set forth in the following description in order to provide a thorough understanding of the invention. These details are provided for the purpose of example; the invention may be practiced according to the claims without some or all of these specific details. For clarity, technical material that is known in technical fields related to the invention has not been described in detail so that the invention is not unnecessarily obscured.

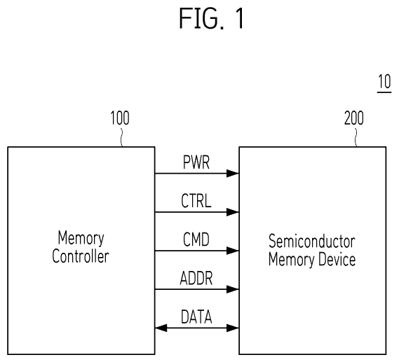

FIG. 1 is a block diagram schematically illustrating a memory system in accordance with an embodiment of the present invention.

Referring FIG. 1, the memory system 10 may include a memory controller 100 and a semiconductor memory device 200, which may represent more than one such device. The semiconductor memory device(s) 200 may be flash memory device(s).

The memory controller 100 may control overall operations of the semiconductor memory device 200.

The semiconductor memory device 200 may perform one or more erase, program, and read operations under the control of the memory controller 100. The semiconductor memory device 200 may receive a command CMD, an address ADDR and data DATA through input/output (I/O) lines. The semiconductor memory device 200 may receive power PWR through a power line and a control signal CTRL through a control line. The control signal CTRL may include a command latch enable (CLE) signal, an address latch enable (ALE) signal, a chip enable (CE) signal, a write enable (WE) signal, a read enable (RE) signal, and the like.

The memory controller 100 and the semiconductor memory device 200 may be integrated in a single semiconductor device such as a solid state drive (SSD). The SSD may include a storage device for storing data therein. When the semiconductor memory system 10 is used in an SSD, operation speed of a host (not shown) coupled to the memory system 10 may remarkably improve.

The memory controller 100 and the semiconductor memory device 200 may be integrated in a single semiconductor device such as a memory card. For example, the memory controller 100 and the semiconductor memory device 200 may be so integrated to configure a PC card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and/or a universal flash storage (UFS).

In another embodiment, the memory system 10 may be provided as one of various components in an electronic device such as a computer, an ultra-mobile PC (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, a radio-frequency identification (RFID) device, as well as one of various electronic devices of a home network, one of various electronic devices of a computer network, one of electronic devices of a telematics network, or one of various components of a computing system.

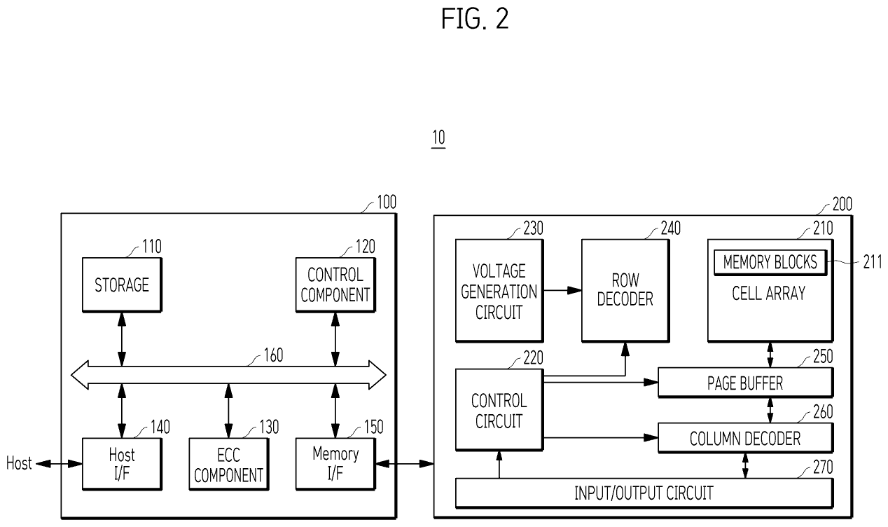

FIG. 2 is a detailed block diagram illustrating a memory system in accordance with an embodiment of the present invention. For example, the memory system of FIG. 2 may depict the memory system 10 shown in FIG. 1.

Referring to FIG. 2, the memory system 10 may include a memory controller 100 and a semiconductor memory device 200. The memory system 10 may operate in response to a request from a host device, and in particular, store data to be accessed by the host device.

The host device may be implemented with any one of various kinds of electronic devices. In some embodiments, the host device may include an electronic device such as a desktop computer, a workstation, a three-dimensional (3D) television, a smart television, a digital audio recorder, a digital audio player, a digital picture recorder, a digital picture player, and/or a digital video recorder and a digital video player. In some embodiments, the host device may include a portable electronic device such as a mobile phone, a smart phone, an e-book, an MP3 player, a portable multimedia player (PMP), and/or a portable game player.

The memory device 200 may store data to be accessed by the host device.

The memory device 200 may be implemented with a volatile memory device such as a dynamic random access memory (DRAM) and/or a static random access memory (SRAM) or a non-volatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), and/or a resistive RAM (RRAM).

The controller 100 may control storage of data in the memory device 200. For example, the controller 100 may control the memory device 200 in response to a request from the host device. The controller 100 may provide data read from the memory device 200 to the host device, and may store data provided from the host device into the memory device 200.

The controller 100 may include a storage 110, a control component 120, which may be implemented as a processor such as a central processing unit (CPU), an error correction code (ECC) component 130, a host interface (I/F) 140 and a memory interface (I/F) 150, which are coupled through a bus 160.

The storage 110 may serve as a working memory of the memory system 10 and the controller 100, and store data for driving the memory system 10 and the controller 100. When the controller 100 controls operations of the memory device 200, the storage 110 may store data used by the controller 100 and the memory device 200 for such operations as read, write, program and erase operations.

The storage 110 may be implemented with a volatile memory such as a static random access memory (SRAM) or a dynamic random access memory (DRAM). As described above, the storage 110 may store data used by the host device in the memory device 200 for the read and write operations. To store the data, the storage 110 may include a program memory, a data memory, a write buffer, a read buffer, a map buffer, and the like.

The control component 120 may control general operations of the memory system 10, and a write operation or a read operation for the memory device 200, in response to a write request or a read request from the host device. The control component 120 may drive firmware, which is referred to as a flash translation layer (FTL), to control general operations of the memory system 10. For example, the FTL may perform operations such as logical-to-physical (L2P) mapping, wear leveling, garbage collection, and/or bad block handling. The L2P mapping is known as logical block addressing (LBA).

The ECC component 130 may detect and correct errors in the data read from the memory device 200 during the read operation. The ECC component 130 may not correct error bits when the number of the error bits is greater than or equal to a threshold number of correctable error bits, and instead may output an error correction fail signal indicating failure in correcting the error bits.

The ECC component 130 may perform an error correction operation based on a coded modulation such as a low-density parity-check (LDPC) code, a Bose-Chaudhuri-Hocquenghem (BCH) code, a turbo code, a turbo product code (TPC), a Reed-Solomon (RS) code, a convolution code, a recursive systematic code (RSC), a trellis-coded modulation (TCM), or a Block coded modulation (BCM). As such, the ECC component 130 may include all circuits, systems or devices for suitable error correction operation.

The host interface 140 may communicate with the host device through one or more of various interface protocols such as a universal serial bus (USB), a multi-media card (MMC), a peripheral component interconnect express (PCI-e or PCIe), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The memory interface 150 may provide an interface between the controller 100 and the memory device 200 to allow the controller 100 to control the memory device 200 in response to a request from the host device. The memory interface 150 may generate control signals for the memory device 200 and process data under the control of the CPU 120. When the memory device 200 is a flash memory such as a NAND flash memory, the memory interface 150 may generate control signals for the memory and process data under the control of the CPU 120.

The memory device 200 may include a memory cell array 210, a control circuit 220, a voltage generation circuit 230, a row decoder 240, a page buffer 250, which may be in the form of an array of page buffers, a column decoder 260, and an input/output circuit 270. The memory cell array 210 may include a plurality of memory blocks 211 which may store data. The voltage generation circuit 230, the row decoder 240, the page buffer array 250, the column decoder 260 and the input/output circuit 270 may form a peripheral circuit for the memory cell array 210. The peripheral circuit may perform a program, read, or erase operation of the memory cell array 210. The control circuit 220 may control the peripheral circuit.

The voltage generation circuit 230 may generate operation voltages of various levels. For example, in an erase operation, the voltage generation circuit 230 may generate operation voltages of various levels such as an erase voltage and a pass voltage.

The row decoder 240 may be in electrical communication with the voltage generation circuit 230, and the plurality of memory blocks 211. The row decoder 240 may select at least one memory block among the plurality of memory blocks 211 in response to a row address RADD generated by the control circuit 220, and transmit operation voltages supplied from the voltage generation circuit 230 to the selected memory blocks.

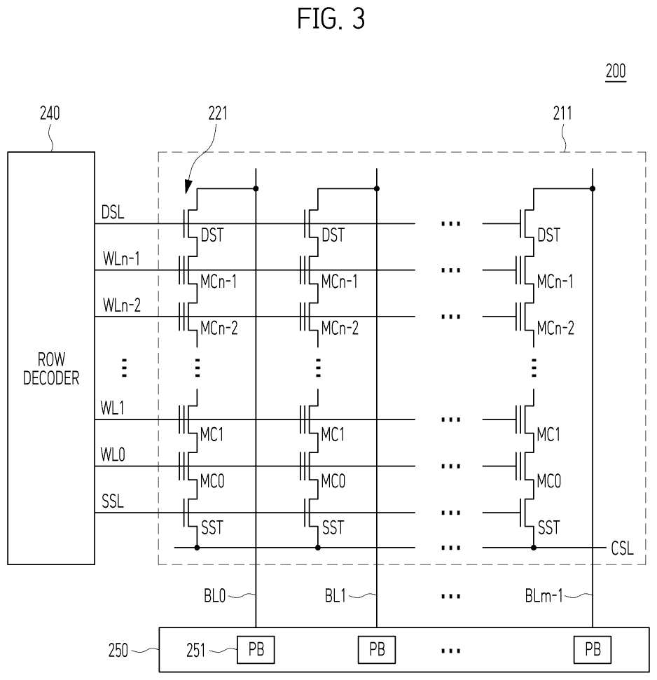

The page buffer 250 may be in electrical communication with the memory cell array 210 through bit lines BL (shown in FIG. 3). The page buffer 250 may precharge the bit lines BL with a positive voltage, transmit data to, and receive data from, a selected memory block in program and read operations, or temporarily store transmitted data, in response to page buffer control signal(s) generated by the control circuit 220.

The column decoder 260 may transmit data to, and receive data from, the page buffer 250 or transmit/receive data to/from the input/output circuit 270.

The input/output circuit 270 may transmit to the control circuit 220 a command and an address, received from an external device (e.g., the memory controller 100), transmit data from the external device to the column decoder 260, or output data from the column decoder 260 to the external device, through the input/output circuit 270.

The control circuit 220 may control the peripheral circuit in response to the command and the address.

FIG. 3 is a circuit diagram illustrating a memory block of a semiconductor memory device in accordance with an embodiment of the present invention. For example, the memory block of FIG. 3 may be any of the memory blocks 211 of the memory cell array 200 shown in FIG. 2.

Referring to FIG. 3, the exemplary memory block 211 may include a plurality of word lines WL0 to WLn-1, a drain select line DSL and a source select line SSL coupled to the row decoder 240. These lines may be arranged in parallel, with the plurality of word lines between the DSL and SSL.

The exemplary memory block 211 may further include a plurality of cell strings 221 respectively coupled to bit lines BL0 to BLm-1. The cell string of each column may include one or more drain selection transistors DST and one or more source selection transistors SST. In the illustrated embodiment, each cell string has one DST and one SST. In a cell string, a plurality of memory cells or memory cell transistors MC0 to MCn-1 may be serially coupled between the selection transistors DST and SST. Each of the memory cells may be formed as a multi-level cell (MLC) storing data information of multiple bits.

The source of the SST in each cell string may be coupled to a common source line CSL, and the drain of each DST may be coupled to the corresponding bit line. Gates of the SSTs in the cell strings may be coupled to the SSL, and gates of the DSTs in the cell strings may be coupled to the DSL. Gates of the memory cells across the cell strings may be coupled to respective word lines. That is, the gates of memory cells MC0 are coupled to corresponding word line WL0, the gates of memory cells MC1 are coupled to corresponding word line WL1, etc. The group of memory cells coupled to a particular word line may be referred to as a physical page. Therefore, the number of physical pages in the memory block 211 may correspond to the number of word lines.

The page buffer array 250 may include a plurality of page buffers 251 that are coupled to the bit lines BL0 to BLm-1. The page buffers 251 may operate in response to page buffer control signals. For example, the page buffers 251 my temporarily store data received through the bit lines BL0 to BLm-1 or sense voltages or currents of the bit lines during a read or verify operation.

In some embodiments, the memory blocks 211 may include a NAND-type flash memory cell. However, the memory blocks 211 are not limited to such cell type, but may include NOR-type flash memory cell(s). Memory cell array 210 may be implemented as a hybrid flash memory in which two or more types of memory cells are combined, or one-NAND flash memory in which a controller is embedded inside a memory chip.

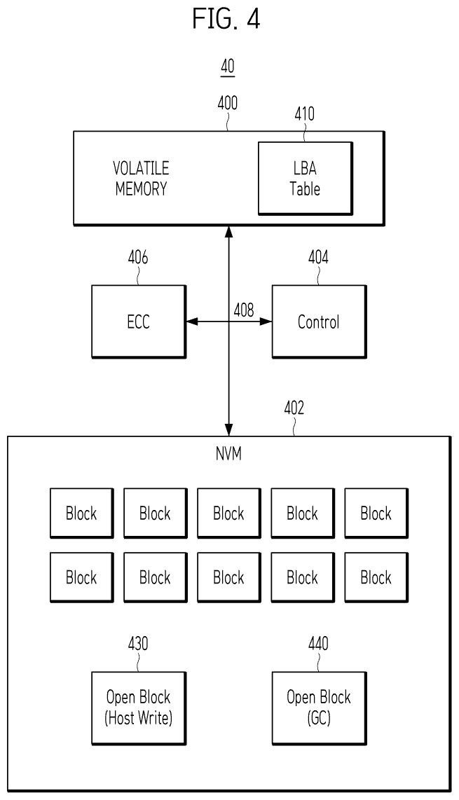

Referring to FIG. 4, a general example of a memory system 40 is schematically illustrated. The memory system 40 may include a volatile memory 400 (e.g., a DRAM), a non-volatile memory (NVM) 402 (e.g., NAND), a control component or control logic 404, such as described herein, an error correcting code (ECC) module 406, such as described herein, and a bus 408 through which these components of the memory system 40 communicate. The volatile memory 400 may include a logical bit address LBA table 410 for mapping physical-to-logical addresses of bits. The NVM 402 may include a plurality of memory blocks (and/or a plurality of super memory blocks), as well as an open block for host writes 430 and an open block for garbage collection (GC) 440. The memory system 40 shows a general memory system. Additional/alternative components that may be utilized with memory systems to effectuate the present invention will be understood to those of skill in the art in light of this disclosure.

As referred to herein, terms such as “NAND” or “NVM” may refer to non-volatile memories such as flash memories which may implement error correcting code processes. Further, “DRAM” may refer to volatile memories which may include components such as controllers and ECC modules.

In embodiments of the present invention, the memory system 10 may include multiple decoders that are configured to decode low-density parity-check (LDPC) codes.

There are many iterative decoding algorithms for LDPC codes, such as bit-flipping (BF) decoding algorithms, belief-propagation (BP) decoding algorithms, sum-product (SP) decoding algorithms, min-sum (MS) decoding algorithms, and Min-Max decoding algorithms.

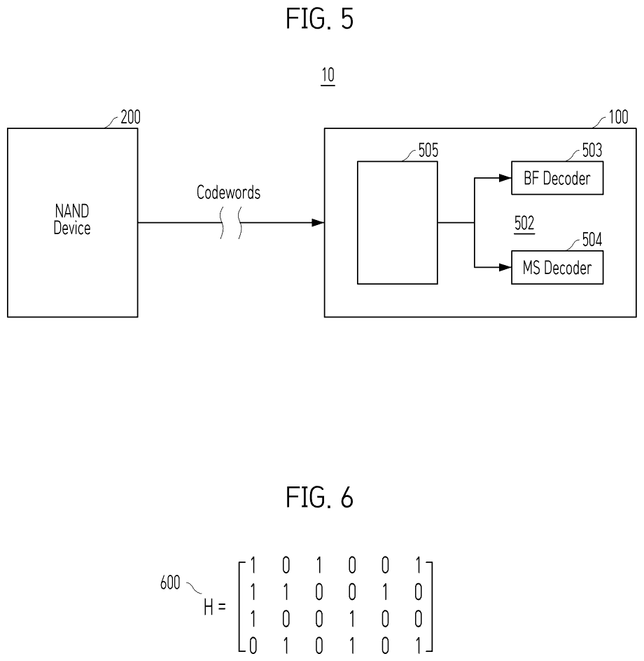

In accordance with embodiments of the present invention, and as shown in FIG. 5, the memory system 10 may include the memory device 200, which may be a NAND device, and the memory controller 100. The memory system 10 may include decoding assembly 502, which includes a bit-flipping (BF) decoder 503 to execute a BF decoding algorithm to decode codewords read from the memory device 501 and a min-sum (MS) decoder 504 to execute an MS decoding algorithm. The BF decoder 503 and the MS decoder 504 may be embodied in the ECC component 130 (shown in FIG. 1) in the memory controller 100 or in any other suitable location. The codewords received from the memory device 200 by the memory controller 100 may be temporarily stored in a buffer or storage 505 of the memory controller 100 before being passed to one or the other of the decoders.

The memory system 10 may include other components (not shown) such as a checksum module, which computes checksums of codewords retrieved from the memory device 200. The checksum module may be embodied within the memory controller 100 before the storage 505. The memory system 10 may further include cyclic redundancy check (CRC) modules disposed downstream of the BF decoder 503 and MS decoder 504, respectively. The CRC modules may be embodied within the memory controller 100 containing a generator polynomial for generation of the CRC codes.

With respect to the two decoding algorithms, MS decoding, performed by its associated decoder 504, is more powerful due to its higher complexity required to process soft input information. However, the less powerful BF decoding, performed by its associated decoder 503, is useful especially when the number of errors is low and when used as detailed below to track convergence of differently weighted column zones.

MS decoding can be used as part of an iterative LDPC decoding. LDPC codes are linear block codes defined by a sparse parity-check matrix H, which consists of zeros and ones. The term “sparse matrix” is used herein to refer to a matrix in which a number of non-zero values in each column and each row is much less than its dimension. The term “column weight” is used herein to refer to the number of non-zero values in a specific column of the parity-check matrix H. The term “row weight” is used herein to refer to number of non-zero values in a specific row of the parity-check matrix H. In general, if column weights of all of the columns in a parity-check matrix corresponding to an LDPC code are similar, the code is referred to as a “regular” LDPC code. On the other hand, an LDPC code is called “irregular” if at least one of the column weights is different from other column weights. Usually, irregular LDPC codes provide better error correction capability than regular LDPC codes.

LDPC codes are usually represented by bipartite graphs. One set of nodes, the variable or bit nodes correspond to elements of the codeword and the other set of nodes, e.g., check nodes, correspond to the set of parity-check constraints satisfied by the codeword. Typically, the edge connections are chosen at random. The error correction capability of an LDPC code is improved if cycles of short length are avoided in the graph. In a (r,c) regular code, each of the n variable nodes (V1, V2, . . . , Vn) has connections to r check nodes and each of the m check nodes (C1, C2, . . . , Cm) has connections to c bit nodes. In an irregular LDPC code, the check node degree is not uniform. Similarly, the variable node degree is not uniform. In quasi-cyclic (QC)-LDPC codes, the parity-check matrix H is structured into blocks of p×p matrices such that a bit in a block participates in only one check equation in the block, and each check equation in the block involves only one bit from the block. In QC-LDPC codes, a cyclic shift of a codeword by p results in another codeword. Here p is the size of square matrix which is either a zero matrix or a circulant matrix. This is a generalization of a cyclic code in which a cyclic shift of a codeword by 1 results in another codeword. The block of p×p matrix can be a zero matrix or cyclically shifted identity matrix of size p×p.

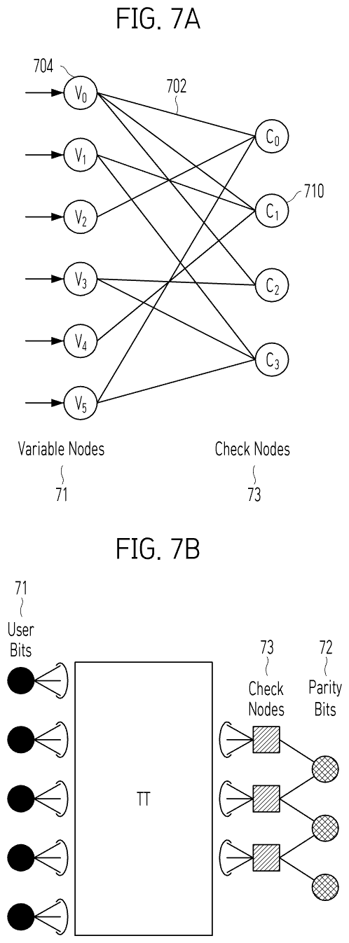

FIG. 6 illustrates an example parity-check matrix H 600, and FIG. 7A illustrates an example bipartite graph corresponding to the parity-check matrix 600.

As shown in FIG. 6, the illustrative parity-check matrix 600 has six column vectors and four row vectors. FIG. 7A shows the network corresponding to the parity-check matrix 600 and represent a bipartite graph. Various types of bipartite graphs are possible, including, for example, a Tanner graph. A Tanner graph representation of an LDPC code, with user bits 71, parity bits 72 and check nodes 73, is shown in FIG. 7B.

In general, the variable nodes correspond to the column vectors in the parity-check matrix 600. The check nodes correspond to the row vectors of the parity-check matrix 600. The interconnections between the nodes are determined by the values of the parity-check matrix 600. Specifically, a “1” indicates the corresponding check node and variable nodes have a connection. A “0” indicates there is no connection. For example, the “1” in the leftmost column vector and the second row vector from the top in the parity-check matrix 600 corresponds to the connection between the variable node 71 and the check node 73.

A message passing algorithm may be used to decode LDPC codes. Several variations of the message passing algorithm exist in the art, such as min-sum (MS) algorithm, sum-product algorithm (SPA) or the like. Message passing uses a network of variable nodes and check nodes, as shown in FIG. 7A.

A hard decision message passing algorithm may be performed. In a first step, each of the variable nodes sends a message to one or more check nodes that are connected to it. In this case, the message is a value that each of the variable nodes believes to be its correct value.

In the second step, each of the check nodes calculates a response to send to the variable nodes that are connected to it using the information that it previously received from the variable nodes. This step can be referred as the check node update (CNU). The response message corresponds to a value that the check node believes that the variable node should have based on the information received from the other variable nodes connected to that check node. This response is calculated using the parity-check equations which force the values of all the variable nodes that are connected to a particular check node to sum up to zero (modulo 2).

At this point, if all the equations at all the check nodes are satisfied, the decoding algorithm declares that a correct codeword is found and it terminates error correction. If a correct codeword is not found, the iterations continue with another update from the variable nodes using the messages that they received from the check nodes to decide if the bit at their position should be a zero or a one by a majority rule. The variable nodes then send this hard decision message to the check nodes that are connected to them. The iterations continue until a correct codeword is found, a certain number of iterations are performed depending on the syndrome of the codeword (e.g., of the decoded codeword), or a maximum number of iterations are performed without finding a correct codeword.

At each iteration of the decoding, the systematic (user) bits 71 and the low-degree parity bits 72 (such as shown in FIG. 7B), may be decoded alternatively. The user bits 71 may be decoded one-by-one using for example MS operations. The low-degree parity bits may be jointly decoded using the results of the user bits 71. The results from the joint decoding may be used for the next iteration.

### BF Decoder With Column Zone Convergence Detection

In an SSD, almost all of the read commands are processed by a BF decoder while a MS decoder only handles less than 5% of the traffic. The BF decoder is typically designed in the way such that the gate-count (GC) and power is minimized at the cost of a poorer error correction capability, as compared to a MS decoder. To improve correction performance for a MS decoder, an irregular code can be used (as described above). Yet, for irregular codes, the throughput and correction performance of a BF decoder are typically degraded.

The present inventors have analyzed the reasons for the degradation when irregular codes are used with a BF decoder. One reason that the inventors found for why a BF decoder does not work well with an irregular code is that the flipping algorithm works poorly when the column weight is low. When the number of check-to-variable nodes is low, the variable node does not have enough information to make a good decision to flip or not to flip. and often makes mistakes and flips to the wrong value. This reduces the correction capability and slows down the BF decoder.

In one embodiment of the disclosure, a novel BF decoder is utilized which can work more effectively with irregular codes. Several methods to improve BF decoder's correction capability and convergence behavior are disclosed below.

In general, the inventors have discovered that one way to improve BF decoding is to freeze the variables that have correct values. To do this, a convergence detection method is introduced to the BF decoder. In one embodiment, minor levels of miss-detection are permissible, meaning that there still may be some errors while the BF detector nevertheless provides a “no error” output. As long as the impact (the actual error rate) is below 1E-3 (0.001), the output of the BF decoder is acceptable as the remaining errors can be decoded by the MS decoder. In one embodiment, the error correction traffic (the number of codewords having bits in error) going to MS decoder is preferably <1% of the total detected errors.

In one embodiment, the convergence behavior of a bit depends on its column weight. High weight columns tend to converge faster than low weight columns. In one embodiment, all columns are separated into, for example, three (3) column weight zones, namely, high, medium and low weight zones. For each zone, it is detected if there are remaining errors within this zone or if it is error-free with high probability. Here, weights greater than 5 can be considered “high” weights, weights from 3, 4, and 5 can be considered “medium” weights, and weights of 1 and 2 can be considered “low” weights. The present invention is not limited to these values.

If a zone has converged, the BF decoder can skip those columns so that the throughput is higher and latency is lower.

### Zone Convergence Detection by Matrix Constraint

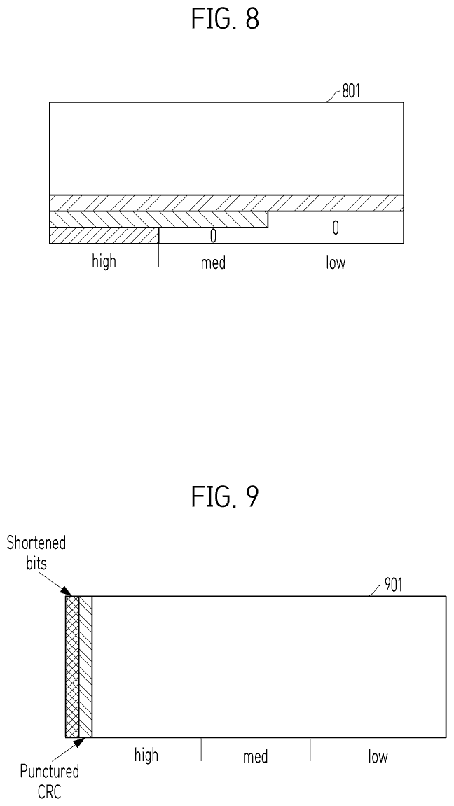

In FIG. 8, there is shown as an example of a parity check matrix 801, where different columns have different relative weights (depicted thereon as high, med, and low) and the three (3) bottom-most rows are selected for BF decoding. The non-shaded part in the three (3) bottom-most rows of the parity check matrix has all zeroes. In this way, the checksum (syndrome weight) of the three (3) bottom-most rows can be used as an indicator of convergence of high/med/low weight columns. When iterations are required to reduce errors in the codewords, the BF decoding can skip those columns that have converged.

To reduce the miss-detection rate, bit-flipping error detection can iterate for example when the total checksum (or syndrome weight) falls into predetermined ranges. Examples of predetermined ranges for the total checksum (CS) which cause iteration include, but are not limited to CS>2000, 500<CS≤2000, 1000<CS≤1500, and 200<CS≤1000. For CS≤200, the BF decoder can decide that no iteration of the bit-flipping is necessary, and skip those columns.

Furthermore, not all column zones of the parity check matrix are necessarily covered when constructing the three (3) bottom-most rows. The number of column zones included is a design choice representing a trade-off between miss-detection rate and correction performance.

### Zone Convergence Detection by Punctured CRC

FIG. 9 is a depiction of another parity check matrix in accordance with one embodiment of the present invention. In this embodiment, zone convergence detection occurs by adding three (3) CRC codes for the high/med/low column zones, and appending the CRC codes to parity check matrix 901. Although the present disclosure is not limited to a 10 bit CRC code, a 10 bit CRC per column zone can be used to make sure that a miss-detection rate is around 1E-3 (0.001). That is, with 10 bits of CRC, the misdetection rate is equal to ½\hat{ }10 which is roughly equal to 1E-3. As a result, 30 bits extra are stored: 10 CRC bits stored for the high column weight zones, 10 CRC bits stored for the medium column weight zones, and 10 CRC bits stored for the low column weight zones. This construction is shown in FIG. 9 showing the CRC bits appended to the parity check matrix 901.

In one embodiment, as shown in FIG. 9, shortened bits can be added to the matrix to align to a circulant boundary. These appended bits are called shortened bits because these bits are used for encoding but are skipped from being with written on NAND. In one embodiment, the shortened bits may store address information. In some embodiments, when LDPC encoding is working on the data with a boundary of a circulant size (e.g., 256 bits), if the address information is not on the circulant boundary, shortened bits can be appended to make the address be on the boundary. In another embodiment, the shortened bits may be all 0s indicating a maximum reliability magnitude. However, making all the shortened bits into 0s is arbitrary. The maximum reliability magnitude means that these all 0s bits has a highest confidence level.

In one illustrative example, if the circulant size is 128 bits, 98 bits can define the shortened bits, and 30 bits can define punctured CRC bits as denoted in FIG. 9 (formed by removing some of the CRC bits). Both the shortened bits and punctured bits in this example are payload bits, and are not part of parity bits of the parity check matrix 901. The shortened bits and punctured bits shown in FIG. 9 will not be stored in NAND. The shortened bits are known to (stored in) the BF decoder, and the punctured bits will be recovered by BF decoder with a high probability if the column weight is high.

In this embodiment, confirming that a column zone satisfies the CRC bits means that the BF decoder can skip those column zones when iterations are required to reduce errors in the codewords. For example, the BF decoder can check the CRC bits for the zone being processed. If the CRC passes, then the BF decoder knows there are no errors in this zone, and can skip this zone.

### Zone Convergence Detection by Checksum

In another embodiment to detect zone convergence, the total checksum CS (or syndrome weight) is utilized. This approach works well when there are only two (2) zones of column weight, namely high and low. To determine a threshold T for the CS, a BF decoder can operate for example on 1E5 (100000) codewords, and record the checksum CS when high weight columns have no errors. This value of threshold T can be set to the maximum value of the recording. For example, a first codeword is analyzed, and the high weight columns contain no error when the checksum CS is equal to 500. For a second codeword, high weight columns contain no error when checksum CS is equal to 550. For a third codeword, the high weight columns contain no error when checksum CS is equal to 450.

After simulation, a length 1E5 (10000) vector CS=[500, 550, 450 . . . ], T=max(cs) is set.

Since the setting of T=max(cs) might be an overkill to most of the codewords, another way to set T to have two (2) thresholds T1 and T2. T1 can be set to be equal to, for example 90 percentile of CS and T2=max(cs). When the checksum is lower than T1, the high weight columns are not processed. When the checksum is in between T1 and T2, high weight columns are skipped once in every two (2) iterations. When the checksum is higher than T2, the high weight columns are processed as normal. This technique allows a soft transition between two decoding modes and provides improved correction and convergence.

### Method for BF Decoding

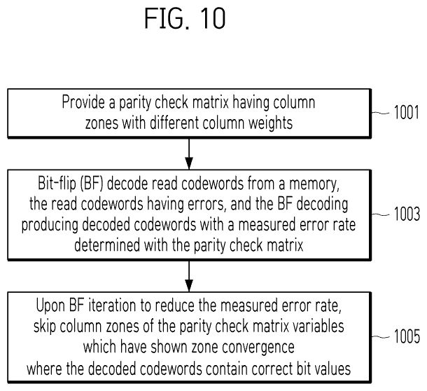

FIG. 10 is a flowchart depicting a method for operating an BF decoder in accordance with one embodiment of the present invention. At 1001, the method provides a parity check matrix having column zones with different column weights. At 1003, the method bit-flip BF decodes read codewords from a memory. The read codewords have errors, and the BF decoding produces decoded codewords with a measured error rate determined with the parity check matrix. At 1005, the method, upon BF iteration to reduce the measured error rate, skips column zones of the parity check matrix variables which have shown zone convergence where the decoded codewords contain correct bit values.

In the one illustrative embodiment, the method may detect the zone convergence by constraining the parity check matrix to have column zones with different column weights and comparing syndrome weights of the column zones as an indicator of the zone convergence. Here, the parity check matrix may have three bottom-most rows and three different column weights, and the three bottom-most rows may have different regions of all-zero entries. Here, a first row of the three bottom-most rows may have all non-zero in all columns of the parity check matrix, the columns having high, medium, and low column weights, a second row of the three bottom-most rows may have non-zero entries only in columns of the parity check matrix with the high and medium weights column, and a third row of the three bottom-most rows may have non-zero entries only in columns of the parity check matrix with the high column weight.

In another illustrative embodiment, the method may detect the zone convergence by adding cyclic redundancy bits to the parity check matrix. Here, the cyclic redundancy bits may comprise bits appended to the parity check matrix for error decoding the read codewords. Here, the error decoding is for decoding the read codewords read from the column zones having high, medium, and low column weights.

In another illustrative embodiment, the method may detect the zone convergence by utilizing checksum calculations on the read codewords read from the column zones having different column weights. Here, the method may determine thresholds for continued BF decoding based on the checksum calculations, and the different column weights may comprise high and low column weights.

### BF Decoding Memory System

In one embodiment of the disclosure, there is provided a memory system (such memory system 10 in FIG. 5) comprising a memory device (such as memory device 200 in FIG. 5), optionally a controller (such as memory controller 100) in communication with and configured to control the memory device, and a bit-flip (BF) decoder (such as BF decoder 503) in communication with a storage of the memory device (the NAND in FIG. 5).

In this memory system embodiment, the BF decoder is configured to: provide a parity check matrix having column zones with different column weights; bit-flip BF decode read codewords from a memory, the read codewords having errors, and the BF decoding producing decoded codewords with a measured error rate determined with the parity check matrix. Upon BF iteration to reduce the measured error rate, the BF decoder is configured to skip column zones of the parity check matrix variables which have shown zone convergence where the decoded codewords contain correct bit values. In this memory system embodiment, the BF decoder may be configured to: detect the zone convergence by constraining the parity check matrix to have column zones with different column weights and comparing syndrome weights of the column zones as an indicator of the zone convergence. Here, the parity check matrix may have three bottom-most rows and three different column weights, and the three bottom-most rows may have different regions of all-zero entries. Here, a first row of the three bottom-most rows may have all non-zero in all columns of the parity check matrix, the columns having high, medium, and low column weights; a second row of the three bottom-most rows may have non-zero entries only in columns of the parity check matrix with the high and medium weights column; and a third row of the three bottom-most rows may have non-zero entries only in columns of the parity check matrix with the high column weight.

In this memory system embodiment, the BF decoder may be configured to: detect the zone convergence by adding cyclic redundancy bits to the parity check matrix. Here, the cyclic redundancy bits may comprise bits appended to the parity check matrix for error decoding the read codewords read from the column zones with different column weights. Here, the BF decoder may be configured to: decode the read codewords from the column zones having high, medium, and low column weights.

In this memory system embodiment, the BF decoder may be configured to: detect the zone convergence by utilizing checksum calculations on the read codewords read from the column zones having different column weights. Here, the BF decoder may be configured to: determine thresholds for continued BF decoding based on the checksum calculations, and the different column weights may comprise high and low column weights.

Although the foregoing embodiments have been described in some detail for purposes of clarity and understanding, the present invention is not limited to the details provided. There are many alternative ways of implementing the invention, as one skilled in the art will appreciate in light of the foregoing disclosure. The disclosed embodiments are thus illustrative, not restrictive.

What is claimed is:

1. A method for operating a bit-flip (BF) decoder, comprising:
providing a parity check matrix having column zones with different column weights;
BF decoding read codewords from a memory, the read codewords having errors, and the BF decoding producing decoded codewords with a measured error rate determined with the parity check matrix; and
upon BF iteration to reduce the measured error rate, skipping column zones of the parity check matrix which have shown zone convergence to correct bit values for the decoded codewords.

2. The method of claim 1, further comprising detecting the zone convergence by constraining the parity check matrix to have column zones with different column weights and comparing syndrome weights of the column zones as an indicator of the zone convergence.

3. The method of claim 2, wherein
the parity check matrix has three bottom-most rows and three different column weights, and
the three bottom-most rows have different regions of all-zero entries.

4. The method of claim 3, wherein
a first row of the three bottom-most rows has all non-zero in all columns of the parity check matrix, the columns having high, medium, and low column weights;
a second row of the three bottom-most rows has non-zero entries only in columns of the parity check matrix with the high and medium weights column; and
a third row of the three bottom-most rows has non-zero entries only in columns of the parity check matrix with the high column weight.

5. The method of claim 1, further comprising detecting the zone convergence by adding cyclic redundancy bits to the parity check matrix.

6. The method of claim 5, wherein
the cyclic redundancy bits comprise bits appended to the parity check matrix for error decoding the read codewords read from the column zones with different column weights.

7. The method of claim 6, wherein
the BF decoding decodes the read codewords from the column zones having high, medium, and low column weights.

8. The method of claim 1, further comprising detecting the zone convergence by utilizing checksum calculations on the read codewords read from the column zones having different column weights

9. The method of claim 8, further comprising determining thresholds for continued BF decoding based on the checksum calculations.

10. The method of claim 9, wherein the different column weights comprise high and low column weights.

11. A memory system comprising:
a memory device; and
a bit-flip (BF) decoder in communication with a storage of the memory device,
wherein the BF decoder is configured to:
provide a parity check matrix having column zones with different column weights,
bit-flip BF decode read codewords from a memory, the read codewords having errors, and the BF decoding producing decoded codewords with a measured error rate determined with the parity check matrix; and
upon BF iteration to reduce the measured error rate, skip process column zones of the parity check matrix variables which have shown zone convergence to correct bit values for the decoded codewords.

12. The system of claim 11, wherein the BF decoder is configured to:
detect the zone convergence by constraining the parity check matrix to have column zones with different column weights and comparing syndrome weights of the column zones as an indicator of the zone convergence.

13. The system of claim 12, wherein
the parity check matrix has three bottom-most rows and three different column weights, and
the three bottom-most rows have different regions of all-zero entries.

14. The system of claim 13, wherein
a first row of the three bottom-most rows has all non-zero in all columns of the parity check matrix, the columns having high, medium, and low column weights;
a second row of the three bottom-most rows has non-zero entries only in columns of the parity check matrix with the high and medium weights column; and
a third row of the three bottom-most rows has non-zero entries only in columns of the parity check matrix with the high column weight.

15. The system of claim 11, wherein the BF decoder is configured to:
detect the zone convergence by adding cyclic redundancy bits to the parity check matrix.

16. The system of claim 15, wherein
the cyclic redundancy bits comprise bits appended to the parity check matrix for error decoding the read codewords read from the column zones with different column weights.

17. The system of claim 16, wherein the BF decoder is configured to:
decode the read codewords from the column zones having high, medium, and low column weights.

18. The system of claim 11, wherein the BF decoder is configured to:
detect the zone convergence by utilizing checksum calculations on the read codewords read from the column zones having different column weights

19. The system of claim 18, wherein the BF decoder is configured to:
determine thresholds for continued BF decoding based on the checksum calculations.

20. The system of claim 19, wherein the different column weights comprise high and low column weights.
